(19) United States
(12) Patent Application Publication
(10) Pub. No.: US 2002/0168810 A1
(43) Pub. Date: Nov. 14, 2002

(54) Lateral nanostructures by vertical processing

(75) Inventor: Thomas N. Jackson, State College, PA (US)

Correspondence Address: Paul D. Greeley, Esq., Ohlandt, Greeley, Ruggiero & Perle, L.L.P., 10th Floor, One Landmark Square, Stamford, CT, 06901-2682, US

(73) Assignee: The Penn State Research Foundation

(21) Appl. No.: 10/112,593

(22) Filed: Mar. 29, 2002

Related U.S. Application Data
(60) Provisional application No. 60/280,235, filed on Mar. 30, 2001.

(51) Int. Cl. H01L 21/00

(52) U.S. Cl. 438/172; 438/52; 438/759

(57) ABSTRACT

The present invention is directed to a process for forming one or more lateral nanostructures on a substrate. The process comprises the steps of: providing a substrate; depositing a first layer on the substrate; forming at least one edge on the first layer; depositing at least one separation layer on the first layer; depositing a third layer on the separation layer; and removing a portion of the separation layer and the third layer from the substrate such that a substantially planar surface is formed exposing the first layer, the separation layer, and the third layer.

This application claims priority from U.S. Provisional Application No. 60/280,235, filed Mar. 30, 2001.

### BACKGROUND OF THE INVENTION

1. Field of the Invention

The present invention relates to lateral nanostructures. More particularly, the present invention relates to lateral nanostructures formed by vertical processing on a substrate.

2. Description of the Prior Art

Nanoscale structures are of interest for a wide variety of device and material investigations. The need to develop such nanostructures is well recognized in the art (Science, Vol. 294, December 2001; C. Zhou, M.R. Deshphande, M. A. Reed, L. Jones II and J. M. Tour, Nanoscale Metal/Self-Assembled Monolayer/Metal Heterostructures, Appl. Phys. Lett. 71 (5), August 1997; Tseng and Ellenbogen, Toward Nonocomputers, Science, Vol. 294, November 2001). Nanoscale structures are typically defined using nanolithography techniques. These techniques include either traditional techniques such as electron beam, x-ray, or advanced optical lithography, or alternative lithographic techniques such as micro- or nano-stamping or contact printing, or scanning probe lithography. However, the resolution of each of these techniques is limited and none is able to routinely achieve extreme nanoscale or molecular scale dimensions.

A prior art approach to forming nanostructures is depicted in FIG. 1. Here a multi-layer structure 10 with a center region 12 of nanothickness separating two thicker regions 14,16 is used. All three layers 12,14,16 can be deposited by a variety of deposition techniques, such as evaporation, sputtering, or chemical vapor deposition. The center region 12 can be of any desired thickness down to atomic dimensions.

However, an important prior art limitation exists in that the defect density for ultrathin separation layers is typically quite large. In the case of conductors or semiconductors separated by a thin insulating layer, this defect density creates short circuits between layers unless the multi-layer area is limited to very small dimensions. Thus, this approach often requires nanolithography even though the layer separation is created by deposition. This in turn makes it difficult to connect contacts or wiring to the small area nanostructure since such connections must also be nanoscale. In addition, the nanostructure formed as described is vertical, that is, the nano-dimension is in the direction normal to the substrate. For many applications lateral nanostructures are required or desirable.

Therefore, there clearly is a need in the art for a process to fabricate lateral nanostructures on substrates, such as conductors or semiconductors with virtually no defects, no short circuits and preferably by means other than nanolithography. This need in the art is satisfied by the present invention, which provides a process for forming lateral nanostructures using primarily vertical processing. The resulting nanostructures are virtually defect free and thus do not require further processing.

### SUMMARY OF THE INVENTION

The present invention provides a process for forming a lateral nanostructure on a substrate. The process comprises the steps of:

(a) providing a substrate;

(b) depositing a first layer on the substrate;

(c) forming at least one edge on the first layer;

(d) depositing at least one separation layer on the first layer;

(e) depositing a third layer on the separation layer; and

(f) removing a portion of the separation layer and the third layer such that a substantially planar surface is formed exposing the first layer, the separation layer, and the third layer.

### DESCRIPTION OF THE DRAWINGS

FIG. 1 is a perspective view of a prior art nanostructure;

FIGS. 2a-d are perspective views of a lateral nanostructure during various process stages according to the process of the present invention;

FIG. 3a is a perspective view of a lateral nanostructure formed from the process of the present invention;

FIG. 3b is an exploded view of the lateral nanostructure depicted in FIG. 3a with a schematically represented molecule placed across the nanostructure;

FIG. 4 is a perspective view of a nanostructure formed from the process of the present invention with a caltrops molecule selectively attached thereto;

FIGS. 5a-e are perspective views of a lateral nanostructure at various process steps according to the present invention; and

FIG. 6 is a perspective view of a lateral nanostructure having two separation layers formed according to the process of the present invention.

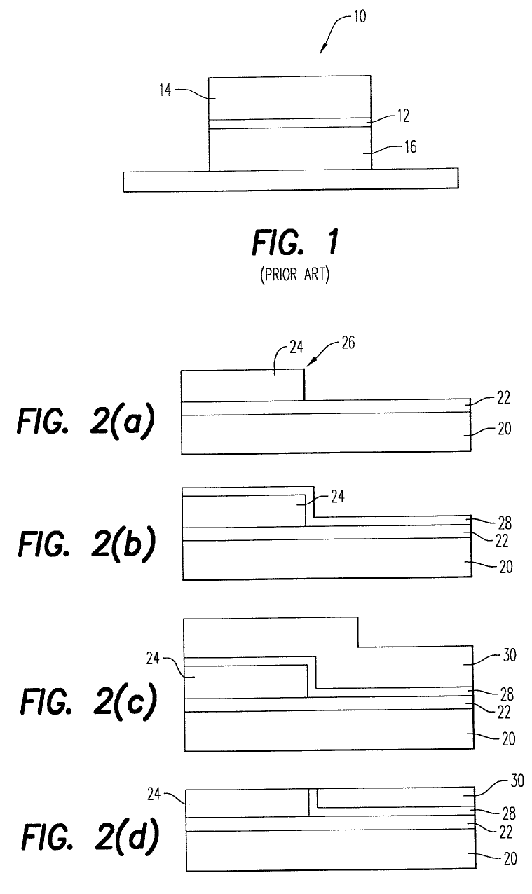

### DETAILED DESCRIPTION OF THE INVENTION

The present invention is directed to a process for fabricating lateral nanostructures using primarily vertical processing. Referring to the Figures and, in particular, FIGS. 2a-d, the process of the present invention is generally illustrated.

Referring to FIG. 2a, a substrate 20 is depicted having a layer 22. Suitable substrates for use with the present invention include, for example, glass, silicon dioxide, polymeric materials, semiconductors such as silicon, germanium, silicon germanium, gallium arsenide, aluminum arsenide, silicon carbide, gallium nitride, aluminum nitride, indium nitride, indium phosphide, indium arsenide, metals, and any combinations thereof.

Layer 22 can be deposited or created on substrate 20 by any suitable process, including, for example, evaporation, sputtering, chemical vapor deposition, oxidation, anodization, ion beam deposition, electrodeposition, plasma deposition, or any combinations thereof. Suitable materials for forming layer 22 include, for example, dielectrics such as silicon dioxide, silicon nitride, aluminum oxide, metals, semiconductors, organic materials, or any combinations thereof and may include multilayers. Alternatively, layer 22 may be omitted if it is desired to form the nanostructure directly on substrate 20.

The process of the present invention begins by depositing a first layer 24 on layer 22 such that an edge 26 is created. First layer 24 can be deposited or created on layer 22 by any suitable process, including, for example, evaporation, sputtering, chemical vapor deposition, oxidation, anodization, ion beam deposition, electrodeposition, plasma deposition, or any combinations thereof. Suitable materials for forming first layer 24 include, for example, copper, gold, aluminum, nickel, platinum, palladium, silver, titanium, tantalum, niobium, hafnium, chromium, other metals, semiconductors, insulators, organic materials, or any combinations thereof.

Edge 26 can be formed by any suitable technique or process. Suitable processes for forming edge 26 include, for example, etching, depositing using a mask technique, such as, for example, lift-off patterning, scribing, or any combinations thereof It should be understood that it is not essential that the profile of edge 26 be vertical. It should also be understood that two or more edges 26 may be formed in layer 24.

Referring to FIG. 2b, a second layer or separation layer 28 is deposited or created on first layer 24. Separation layer 28 can be deposited or created by any suitable process including, for example, evaporation, sputtering, chemical vapor deposition, oxidation, anodization, ion beam deposition, electrodeposition, plasma deposition, or any combinations thereof. Suitable materials for forming separation layer 28 include, for example, silicon dioxide, silicon nitride, aluminum oxide, glass, other insulators, metals, semiconductors, organic materials, or any combinations thereof.

Depending on the process used to create first layer 24, separation layer 28 may cover both the surface of first layer 24 and the adjacent surface of layer 22 or only the surface of first layer 24. Separation layer 28 can be either conformal (same thickness everywhere) or non-conformal (different thickness in different regions).

Referring to FIG. 2c, a third layer 30 is deposited or created on separation layer 28. Third layer 30 can be deposited or created by any suitable process including, for example, evaporation, sputtering, chemical vapor deposition, oxidation, anodization, ion beam deposition, electrodeposition, plasma deposition, or any combinations thereof. Suitable materials for forming third layer 30 include, for example, copper, gold, aluminum, nickel, platinum, palladium, silver, titanium, tantalum, niobium, hafnium, chromium, other metals, semiconductors, insulators, organic materials, or any combinations thereof.

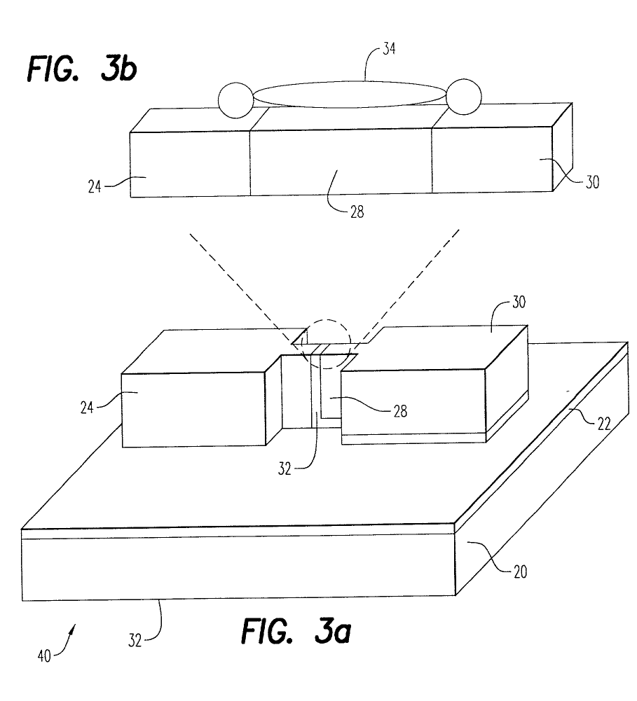

Referring to FIG. 2d, a planarization technique is used to remove the excess second layer 30 and a portion of separation layer 28 to create the lateral nanostructure 32, in which all three layers 24, 28, 30 are exposed. Any suitable planarization technique can be used. Suitable planarization techniques include, for example, chemical-mechanical polishing (CMP), organic reflow and etchback, inorganic reflow and etchback, or any combinations thereof Referring to FIG. 3 a, structure 40 is depicted with a small area, lateral nanostructure 32, completed by a simple patterning technique. Because the vertical extent of the nanostructure can be controlled to a very small dimension, typically about 1 nm to about 10,000 nm, by deposition and removal processes, it is easy to create small area nanostructures even when fairly crude, for example, micron-scale patterning is used for this final step. If nanolithograpy is used, extremely small areas are possible, if desired. In addition, connections to lateral nanostructures created by this technique are readily and naturally obtained and may be included as part of the final patterning step as shown.

Referring to FIG. 3b, a molecule 34 is depicted as being selectively attached to layers 24, 30 of the lateral nanostructure 32, on each side of separation layer 28.

With the process of the present invention, the separation layer 28 can be formed such that the first layer 24 and third layer 30 are separated by a width of secondary layer 28 with nanoscale dimension. Widths as small as 1 nm, or even smaller, are in principle possible, with sub-nanometer control of the dimension from about 1 nm to about 1000 nm or even greater.

The present invention can be further understood by the following examples.

### EXAMPLE 1

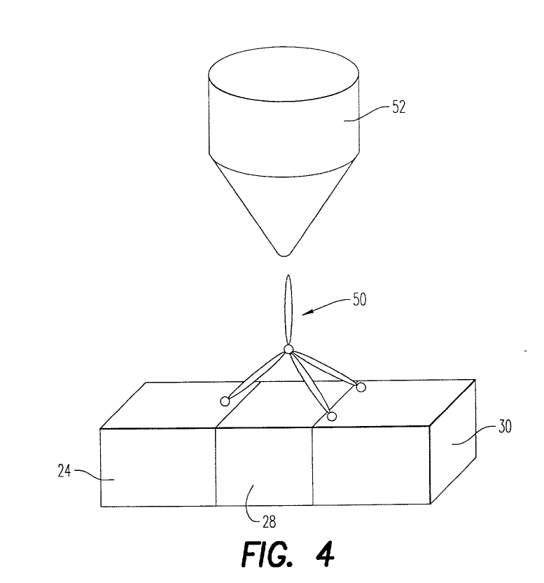

The process of the present invention can be used to create lateral nanostructures with dimensions ranging from atomic scale to any desirable larger size. Such lateral nanostructures are useful for making multiple connections to molecules and other nanosize devices. By way of example, referring to FIG. 4, a separation region 32 of a lateral nanostructure with a caltrops molecule 50 selectively attached to different metals 24,30 on each side of the separation region 32, is illustrated. A scanning tunneling microscope tip 52 is shown approaching the caltrops molecule 50 so that three-terminal measurements of molecular characteristics can be made.

### EXAMPLE 2

The process of the present invention can be used to form a lateral nanogap test bed. Controllably positioning two electrodes within a few tens of angstroms from one another is not a trivial task. Non-optical lithography techniques, such as electron-beam lithography and x-ray lithography, have maximum resolutions near 15 nm. Therefore, these techniques used in a conventional manner, cannot provide the means of creating a 2 nm gap. However, thin films can be deposited with angstrom thickness resolution. In the lateral nanogap fabrication process, a thin-film dictates this electrode spacing rather than lithography.

The following example demonstrates a process for forming a Pt/Al₂O₃/Au lateral nanogap test bed.

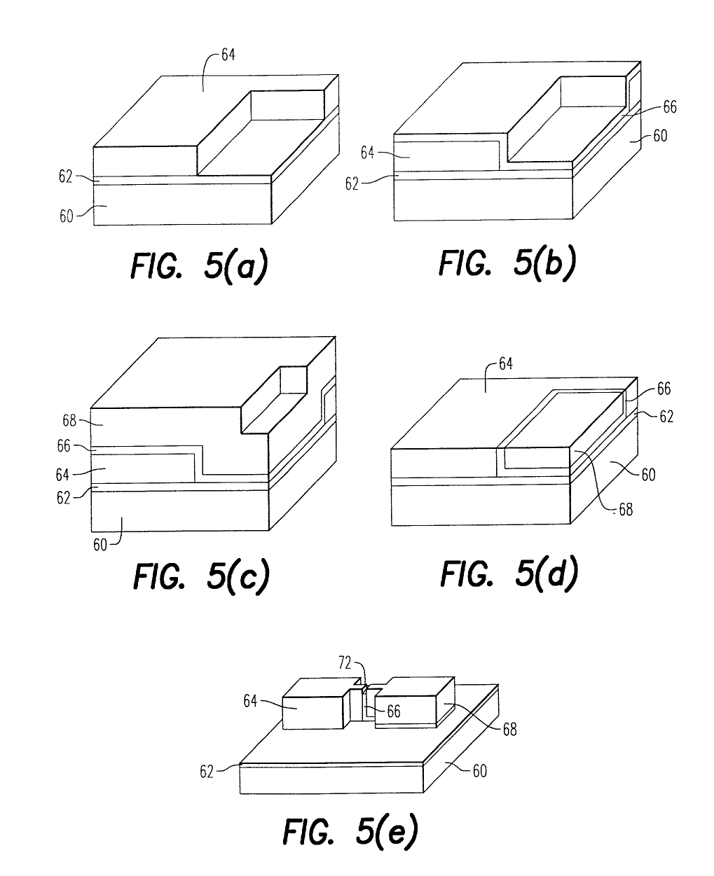

The first step to creating the lateral nanogap test bed is to select an appropriate substrate 60. For convenience a silicon wafer is used. A thick oxide is grown to minimize coupling between the electrodes through the substrate. Double-layer lithography is performed to define the regions where the first metal will be removed following deposition. A 5 nm chromium adhesion layer 62 and a 50 nm platinum layer 64 are ion-beam deposited. Platinum has a very low CMP removal rate in nearly all slurries and is an excellent material for molecular self-assembly. Metal lift-off is performed by first soaking the substrate in a warm acetone bath followed by subsequent ultrasonic cleanings, one in clean acetone and the other in isopropyl alcohol. FIG. 5a shows the structure at this point in processing. Residual photoresist is removed in an oxygen plasma.

As illustrated in FIG. 5b, a thin dielectric spacer 66 is deposited either by plasma-enhanced chemical-vapor deposition (PECVD) or ion-beam sputtering. A low-deposition rate (0.02 nm/s) is attainable when depositing a dielectric by ion-beam sputtering. This element of control is important when using a deposition to define a critical dimension. Aluminum oxide is chosen based on its ability to adhere to an inert surface such as that of platinum. To improve sidewall coverage, the substrate holder is heated to 80° C. and rotated during deposition.

As depicted in FIG. 5c, a 100 m gold layer 68 is deposited following the deposition of a 2 nm chromium adhesion layer (not shown).

As illustrated in FIG. 5d, once the gold layer 68 has been deposited, it is removed down to the chromium adhesion layer by chemical mechanical polishing (CMP). The CMP polishing slurry is made by combining a dilute gold etch [210 g H₂O: 2.05 g KI: 1.03 g I₂] with 0.03 μm alumina abrasive. Both the polishing pad and chuck (not shown) are rotated counter clockwise with a down-force of 50 N. The average polishing rate of gold is approximately 5 nm/s while that of platinum is nearly zero. CMP was performed using a Struers Abramatic polishing system.

After substrate 60 is removed from the polishing chuck and cleaned, the second and final lithography step is performed. The photoresist is hardbaked at 135° C. for 10 min to make it more durable for the subsequent processing. A 15 min ion-milling operation is done in steps of 2 min separated by 3 min breaks. This will prevent excessive local heating and preserve the photoresist mask. Next, the photoresist is stripped in a strong solvent followed by an oxygen plasma etch. A chrome wet etch is then done to insure exposure of the dielectric spacer. The final step is a brief etch in warm H₂SO₄ to form a recess 72 in the aluminum oxide 66. FIG. 5e depicts the final structure.

It should be understood that while the invention is depicted above as a substrate having only one lateral nanostructure, the substrate can just as easily be formed with two or more lateral nanostructures on a single substrate. Since patterned features typically have two or more edges, forming two or more lateral nanostructures on the substrate is as simple as forming one. Arrays and the like are also possible, with spacing set by whatever lithographic technique is used.

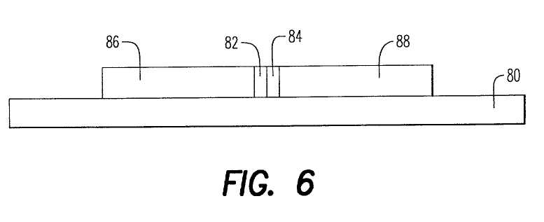

It should also be understood that the separation layer of the present invention depicted above, in the middle of the lateral nanogap structure, does not need to be a single material. Multiple separation layers may be formed in the same manner described for forming the single separation layer, as noted above. In addition, the multiple separation layers may be formed from the same material noted above for the single separation material. By way of example, referring to FIG. 6, a substrate 80 having two separation layers 82, 84 formed between a first layer 86 and a second layer 88, is depicted. Each separation layer may be formed to have a width of about 1 nm to about 1000 nm.

It is also possible to repeat the process of the present invention to form new lateral nanostructures on top of those lateral nanostructures formed earlier or at their edges.

It should be understood that the foregoing description and examples are only illustrative of the present invention. Various alternatives and modifications can be devised by those skilled in the art without departing from the invention. Accordingly, the present invention is intended to embrace all such alternatives, modifications and variances.

What is claimed is:

1. A process for forming one or more lateral nanostructures on a substrate comprising the steps of:
(a) providing a substrate;
(b) depositing a first layer on said substrate;
(c) forming at least one edge on said first layer;
(d) depositing at least one separation layer on said first layer;
(e) depositing a third layer on said separation layer; and
(f) removing a portion of said separation layer and said third layer such that a substantially planar surface is formed exposing said first layer, said separation layer, and said third layer.

2. The process of claim 1, wherein said substrate is selected from the group consisting of: glass, silicon dioxide, polymeric materials, semiconductors such as silicon, germanium, silicon germanium, gallium arsenide, aluminum arsenide, silicon carbide, gallium nitride, aluminum nitride, indium nitride, indium phosphide, indium arsenide, metals, and any combinations thereof.

3. The process of claim 1, wherein said first layer is selected from the group consisting of: copper, gold, aluminum, nickel, platinum, palladium, silver, titanium, tantalum, niobium, hafnium, chromium, other metals, semiconductors, insulators, organic materials, and any combinations thereof.

4. The process of claim 1, wherein said first layer is deposited on said substrate by a means selected from the group consisting of: evaporation, sputtering, chemical vapor deposition, oxidation, anodization, ion beam deposition, electrodeposition, plasma deposition, and any combinations thereof.

5. The process of claim 1, wherein said edge is formed by a means selected from the group consisting of: etching, masking, scribing, and any combinations thereof.

6. The process of claim 1, wherein said separation layer is selected from the group consisting of silicon dioxide, silicon nitride, aluminum oxide, glass, other insulators, metals, semiconductors, organic materials, and any combinations thereof.

7. The process of claim 1, wherein said separation layer is deposited on said first layer by a means selected from the group consisting of: evaporation, sputtering, chemical vapor deposition, oxidation, anodization, ion beam deposition, electrodeposition, plasma deposition, and any combinations thereof.

8. The process of claim 1, wherein said third layer is selected from the group consisting of: copper, gold, aluminum, nickel, platinum, palladium, silver, titanium, tantalum, niobium, hafnium, chromium, other metals, semiconductors, insulators, organic materials, and any combinations thereof.

9. The process of claim 1, wherein said third layer is deposited on said separation layer by a means selected from the group consisting of: evaporation, sputtering, chemical vapor deposition, oxidation, anodization, ion beam deposition, electrodeposition, plasma deposition, and any combinations thereof.

10. The process of claim 1, wherein said separation layer and said third layer are removed by a planarization means.

11. The process of claim 10, wherein said planarization means is selected from the group consisting of: chemical mechanical polishing, organic reflow and etchback, inorganic reflow and etchback, and any combinations thereof.

12. The process of claim 1, wherein said separation layer of said substantially planar surface has a width of about 1 nm to about 1000 nm.
